(19) United States
(12) Patent Application Publication
(10) Pub. No.: US 2015/0364480 A1
(43) Pub. Date: Dec. 17, 2015

(54) Reducing Retention Loss in Analog Floating Gate Memory

(71) Applicant: Texas Instruments Incorporated, Dallas, TX (US)

(72) Inventor: Allan T. Mitchell, Heath, TX (US)

(21) Appl. No.: 14/546,009

(22) Filed: Nov. 18, 2014

Related U.S. Application Data
(60) Provisional application No. 62/011,359, filed on Jun. 12, 2014.

(51) Int. Cl. H01L 27/115; H01L 21/326; H01L 21/324

(52) U.S. Cl. CPC H01L 27/11521; H01L 21/324; H01L 21/326

(57) ABSTRACT

A conditioning process for integrated circuits including floating-gate devices, such as floating-gate capacitors or transistors in analog or other circuits in which the devices are to be programmed to a specific level. Following initial programming of the floating-gate devices to a specific programmed level, the integrated circuits are subjected to a conditioning bake, followed by re-trim back to the initial programmed level. That portion of the charge at the floating-gate device that was weakly held is removed by the conditioning bake, while the re-trim replaces that charge with more strongly held (i.e., higher activation energy) programmed charge.

### CROSS-REFERENCE TO RELATED APPLICATIONS

This application claims priority, under 35 U.S.C. §119(e), of Provisional Application No. 62/011,359, filed Jun. 12, 2014, incorporated herein by this reference.

### STATEMENT REGARDING FEDERALLY SPONSORED RESEARCH OR DEVELOPMENT

Not applicable.

### BACKGROUND OF THE INVENTION

This invention is in the field of integrated circuit electrical manufacture. Embodiments of this invention are more specifically directed to post-fabrication processing of integrated circuits including analog floating gate memory cells to improve data retention capability.

An increasingly important type of semiconductor integrated circuits are those which implement analog circuit functions, in which input and output signals and information are communicated and processed in the analog domain. Typically, analog integrated circuit functions rely on reference levels (voltages and currents) that are established and regulated on-chip. Proper functioning of the analog integrated circuit, and particularly such functioning over variations in power supply voltage, temperature, and other operating conditions, often critically depends on the stability of reference voltages and currents over such variations. However, manufacturing variations reflected in physical parameters of the integrated circuits can affect the reference levels as generated in these integrated circuits. Accordingly, many analog integrated circuits include some ability to “trim” or adjust the on-chip precision reference circuits, as well as other circuit functions within those integrated circuits. Trimming is typically performed at manufacture, after electrical measurement or other evaluation of the performance of the raw circuit as manufactured.

Recently, programmable non-volatile memory elements have been considered for use as trimming elements, for example in replacement of fuses or antifuses. Examples of these non-volatile memory elements include floating-gate metal-oxide-semiconductor (MOS) transistors, in which the state of the transistor is defined by charge trapped at a floating gate electrode, such as a floating capacitor plate. Programming of the device is accomplished through such mechanisms as Fowler-Nordheim tunneling and hot carrier injection. Programming of floating-gate structures is attractive as a trimming technique because of the precision to modern programming methods can set the charge, and because this programming operation is a purely electrical process. An example of such a programmable voltage reference circuit is described in Roman, et al., “A 1 μA Bandgap-Less Programmable Voltage Regulator”, 56th International Midwest Symposium on Circuits and Systems, (IEEE, 2013), pp. 5-8, incorporated herein by this reference.

However, trimming of circuit parameters by way of floating-gate elements relies on retention of the trapped charge at the floating gate for the life of the device, considering that the trimming may only be available at the time of manufacture (e.g., before packaging). But conventional floating-gate structures in analog integrated circuits have been observed to exhibit some degree of charge leakage over time, which results in degradation of trimmed levels in the circuits relying on those structures. As such, while the small chip area required by analog floating-gate technology for certain analog circuits such as bandgap reference circuits is attractive, the charge retention capability of these devices is often not sufficiently reliable for use in certain applications, particularly those intended for use in high-temperature environments such as remote sensors and systems (e.g., in machine-to-machine networks).

By way of background, this data retention vulnerability has been addressed by the use of specific dielectric films for those analog floating-gate capacitors. But this specific construction necessarily increases the manufacturing cost of the integrated circuits by requiring additional dielectric deposition processes, among other additional process steps such as the deposition and patterning of an additional conductor layer for those capacitors. For example, it is known to construct the analog floating-gate device as a double-level polysilicon device, in which a dedicated dielectric film that defines tunneling regions is formed between the two polysilicon levels. This approach requires an additional deposition process for the separate tunneling dielectric film and, because this film is relatively thick, presents a relatively small capacitance per unit area.

By way of further background, the phenomenon of stress-induced leakage current (SILC) in dielectric films such as silicon dioxide has been observed in the art. According to the conventional model for SILC, defects in the silicon dioxide structure are created by electrical stress across the film. These defects serve as charge traps, such that electrons or holes can be trapped within the dielectric film. Floating-gate devices that are programmed by Fowler-Nordheim or other tunneling across a thin dielectric film are known to be vulnerable to this mechanism, as a portion of the programming charge crossing the dielectric film can become trapped at the stress-induced sites.

### BRIEF SUMMARY OF THE INVENTION

Disclosed embodiments provide a method of improving the as-manufactured data retention capability of floating-gate memory devices.

Disclosed embodiments provide such a method that can be efficiently implemented with little additional manufacturing cost.

Disclosed embodiments provide such a method that provides such improved data retention performance without requiring additional deposition processes.

Disclosed embodiments provide such a method that enables the use of analog floating-gate devices in precision reference circuits, for example as replacement for bandgap reference circuits.

Other objects and advantages of the disclosed embodiments will be apparent to those of ordinary skill in the art having reference to the following specification together with its drawings.

According to certain embodiments, an integrated circuit including a floating-gate capacitors that is to be programmed to a desired analog level is manufactured according to the desired process technology, and the floating-gate capacitor is electrically programmed to the desired analog level. Following that programming, or trimming, the integrated circuit is subjected to a conditioning bake at an elevated temperature for a selected duration. The integrated circuit is then again electrically programmed to restore the desired analog level.

According to some embodiments, a plurality of integrated circuits, each including at least one circuit including a programmable floating-gate device, are fabricated in wafer form. In a first electrical test of the integrated circuits, the floating-gate devices in the plurality of integrated circuits are programmably trimmed to a selected analog level. Following the first electrical test, the integrated circuits are conditioned by a bake at a time and temperature selected according to an activation energy of a charge leakage mechanism. Following the bake, the devices are re-trimmed to a selected level.

### BRIEF DESCRIPTION OF THE SEVERAL VIEWS OF THE DRAWING

FIG. 1 is an electrical diagram, in schematic form, of a programmable floating gate device with which embodiments of the invention may be used.

FIGS. 2a and 2b are plan and cross-sectional views, respectively, of the physical construction of the device of FIG. 1.

FIGS. 3a and 3b are plots of data retention performance of a sample of analog floating-gate integrated circuits.

FIG. 4 is a flow diagram illustrating a method of fabricating floating-gate devices with improved data retention, according to embodiments.

FIG. 5 is a series of plots of time versus temperature used in selection of parameters for the conditioning bake.

### DETAILED DESCRIPTION OF THE INVENTION

The one or more embodiments described in this specification are implemented into an integrated circuit including a programmable circuit of a type known in the art as an analog floating-gate circuit, as it is contemplated that such implementation is particularly advantageous in that context. However, it is also contemplated that this invention may be beneficially applied to in other applications, for example floating-gate digital memory cells, particularly those intended to store more than one digital bit per cell. Accordingly, it is to be understood that the following description is provided by way of example only, and is not intended to limit the true scope of this invention as claimed.

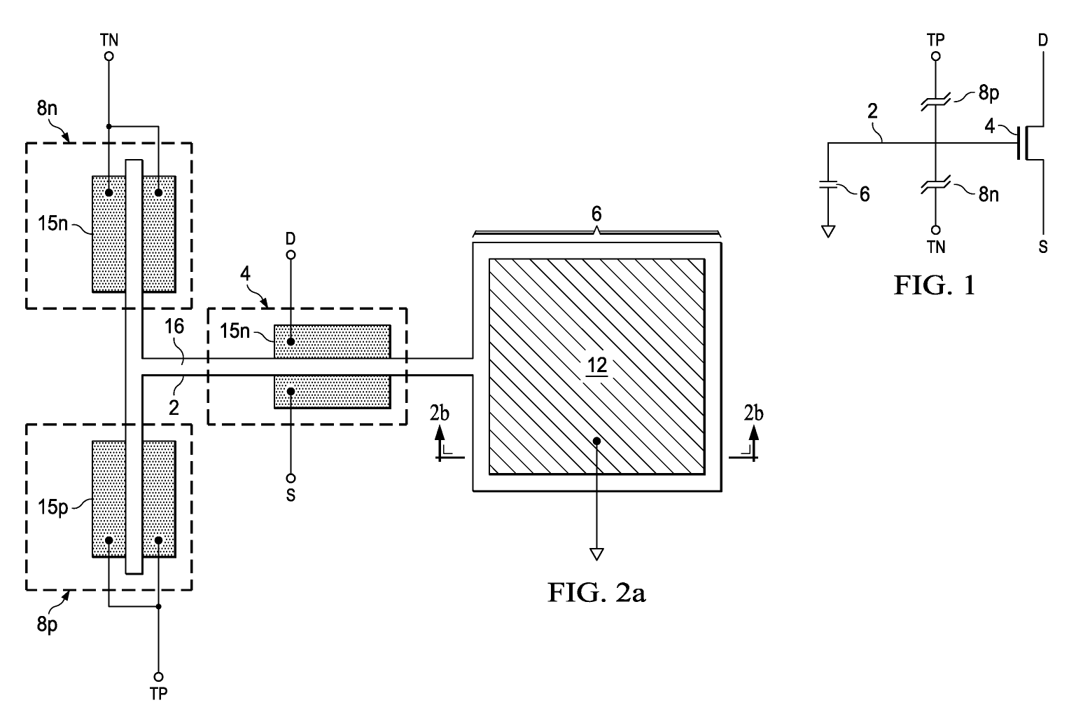

FIG. 1 is an electrical schematic illustrating the arrangement of a conventional analog floating-gate circuit, in connection with which embodiments of this invention may be used. This analog floating-gate circuit includes an electrically floating electrode serving multiple functions. Specifically, analog floating-gate electrode 2 in this circuit of FIG. 1 serves as the gate electrode for metal-oxide-semiconductor (MOS) transistor 4, and as a first plate of storage capacitor 6. Transistor 4 may be at an input of an analog circuit or other function, such as an amplifier or the like. A second plate of storage capacitor 6 is coupled to a reference voltage, namely ground in this example. In operation, the voltage stored across storage capacitor 6 determines the voltage at the gate of MOS transistor 4, and thus the extent to which transistor 4 conducts between drain D and source S, for a given drain-to-source bias.

In this arrangement, analog floating-gate electrode 2 is programmable to a particular analog state by way of tunnel capacitors 8p, 8n. Analog floating-gate electrode 2 serves also as a first plate of each of these tunnel capacitors 8p, 8n. In this example, a second plate of tunnel capacitor 8p is connected to a terminal TP, while a second plate of tunnel capacitor 8n is connected to a terminal TN. The capacitor dielectric for tunnel capacitors 8p, 8n is contemplated to be relatively thin, to allow mechanisms such as Fowler-Nordheim tunneling to transfer charge between terminals TP, TN and analog floating-gate electrode 2, depending on the bias. Tunnel capacitors 8p, 8n permit both the programming of stored charge onto floating-gate electrode 2, and also removal of that stored charge (“erase”); in many implementations in which erase is not necessary or desirable, only one of these tunnel capacitors 8p, 8n is implemented.

In operation, the programming of analog floating-gate electrode 2 by electrons tunneling through tunnel capacitor 8n is performed by applying a pulse of an appropriate negative voltage to terminal TN, relative to the voltage at terminal TP and to the ground reference voltage at the opposite plate of storage capacitor 6. An example of such a “programming” pulse, for a fully programmed level, is a voltage of about −11 volts at terminal TN relative to terminal TP and ground, for on the order of 20 msec. The voltage divider of capacitors 8n, 8p, 6 will result in most of that voltage appearing across tunnel capacitor 8n, enabling electrons to tunnel through its capacitor dielectric to analog floating-gate electrode 2. Those electrons will then be trapped at analog floating-gate electrode 2, considering that there is no direct (i.e., DC) connection between analog floating-gate electrode 2 and any other circuit element. Conversely, electrons can be removed from analog floating-gate electrode 2 by applying an appropriate positive voltage at terminal TP relative to terminal TN and to the ground reference voltage at the opposite plate of storage capacitor 6. The voltage divider of capacitors 8n, 8p, 6 will result in most of that voltage appearing across tunnel capacitor 8p, causing electrons that are trapped on analog floating-gate electrode 2 to tunnel through its capacitor dielectric to terminal TP. An example of such a “erase” pulse, to remove a fully programmed level, is a voltage of about +11 volts at terminal TP relative to terminal TN and ground, for on the order of 20 msec. The duration of the program and erase pulses can be adjusted to precisely set the charge state at analog floating-gate electrode 2. Following programming, the trapped charge on analog floating-gate electrode 2 will establish a voltage across storage capacitor 6, and thus a gate voltage for MOS transistor 4 that controls its conduction. Tunnel capacitors 8n, 8p thus enable precise setting of the charge at analog floating-gate electrode 2, and thus precise adjustment of the analog state of the circuit including MOS transistor 4.

The analog floating gate circuit of FIG. 1 is useful in various circuit environments, including voltage and current reference circuits, programmable gate array structures, trim capability for analog circuits and reference circuits in digital circuits, level shift circuits, multi-bit EEPROM memory cells (i.e., in which each floating gate memory cell is capable of storing intermediate levels), and the like. Those skilled in the art having reference to this specification will readily comprehend these, and other, alternative uses of embodiments of this invention.

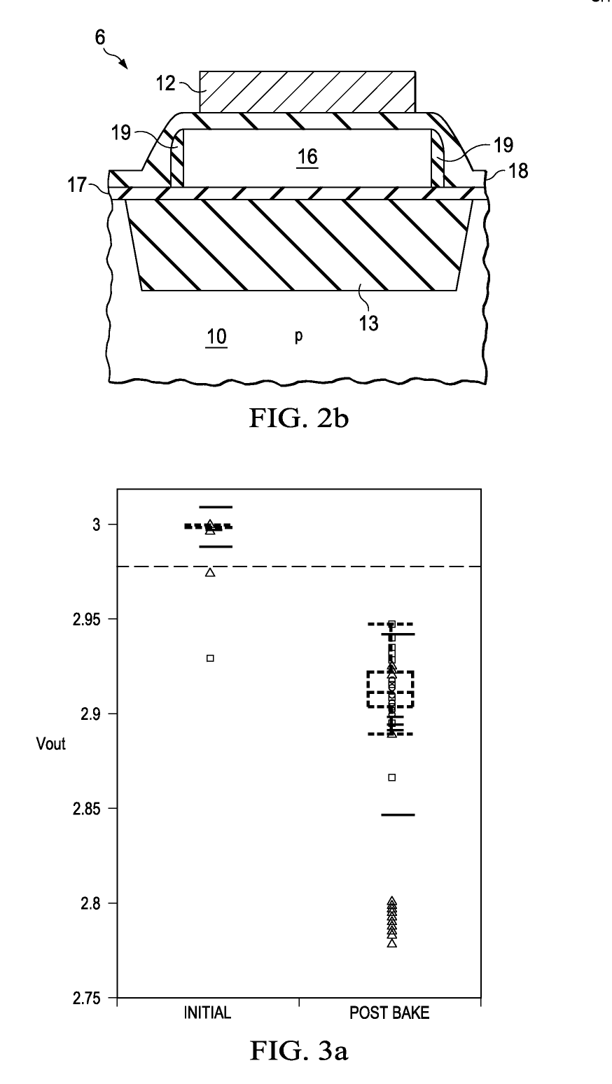

FIG. 2a illustrates, in plan view, the construction of an analog floating-gate structure such as that electrically shown in FIG. 1, and in connection with which embodiments may be used; FIG. 2b illustrates, in cross-section, the construction of capacitor 6. It is contemplated that the sizes of elements shown in FIGS. 2a and 2b are not necessarily to scale, relative to one another. For example, the widths of elements shown in FIG. 2a may in actuality be substantially narrower, relative to the length of the same element, than that shown; similarly, the relative thicknesses of elements in the cross-sectional views of FIG. 2b may not correspond to that in actual devices. In any case, it is contemplated that these structures may be fabricated by way of conventional manufacturing technology, including at those process nodes extending into the sub-micron regime. It is therefore contemplated that those skilled in the art having reference to this specification will be readily able to adapt the structures of FIGS. 2a and 2b in the desired manufacturing technology, without undue experimentation.

As shown in FIG. 2a, analog floating-gate electrode 2 is constructed of polycrystalline silicon (polysilicon) element 16, which extends over the surface of a semiconductor wafer (or over a semiconductor surface layer, in the silicon-on-insulator context) in forming multiple devices or components. Polysilicon element 16 is typically doped to a desired conductivity type and concentration, to be conductive to the desired extent; for example by way of n-type doping for this example in which MOS transistor 4 is n-channel. Polysilicon element 16 has a widened portion at its end serving as a lower plate of storage capacitor 6, and is otherwise narrower, for example at a minimum feature size for the manufacturing technology. As shown in FIG. 2b for storage capacitor 6, the lower plate portion of polysilicon element 16 overlies trench isolation dielectric structure 13. Gate dielectric 17, for example formed of deposited or thermal silicon dioxide, is disposed between the surface of isolation dielectric structure 13 and polysilicon element 16, and will also underlie polysilicon element 16 at those locations at which it overlies active regions (i.e., at transistor 4 and tunnel capacitors 8p, 8n). In this example, the surface into which isolation dielectric structure 13 is formed is the top surface of p-type silicon substrate 10. Upper plate 12 of storage capacitor 6 is formed of a metal such as tantalum nitride, and overlies the widened portion of polysilicon element 16 at this location. In this embodiment of the invention, capacitor dielectric 18 is formed of one or more dielectric layers, for example silicon nitride, silicon dioxide, or a combination of these or other dielectric materials.

Referring back to FIG. 2a, transistor 4 and tunnel capacitors 8p, 8n are constructed along the portion of polysilicon element 16 defining analog floating-gate electrode 2 overlying active regions (i.e., semiconductor portions not underlying isolation dielectric structures 13). MOS transistor 4 is defined where polysilicon element 16 overlies an active region of p-type substrate 10, separated therefrom by gate dielectric 17; heavily-doped n-type source/drain regions 15ₙ are formed into the p-type active region on opposite sides of polysilicon element 16 in the conventional self-aligned fashion. Top side contacts from an overlying metal conductor, and corresponding to terminals D, S as in the circuit of FIG. 1, are made through an interlevel dielectric layer to source/drain regions 15ₙ.

Tunnel capacitor 8n is constructed essentially similarly as n-channel MOS transistor 4, where polysilicon element 16 overlies an instance of a p-type active region (separated by gate dielectric 17); heavily-doped n-type source/drain regions 15ₙ are formed at that location similarly as for transistor 4. Because top side contacts to source/drain regions 15ₙ are both connected to terminal TN, tunnel capacitor 8n operates as a capacitor rather than a transistor. Tunnel capacitor 8p is constructed essentially similarly as tunnel capacitor 8n, but at a location at which polysilicon element 16 overlies an n-type active region, such as the surface of an n-well formed into substrate 10. Top side contacts to p-type source/drain regions 15ₚ on either side of polysilicon element 16 are connected to terminal TP, so that tunnel capacitor 8p operates as a capacitor.

In the example shown in FIG. 2a, the difference in relative area between tunneling capacitors 8p, 8n, on one hand, and storage capacitor 6, on the other hand, along with any differences in the capacitor dielectric materials and thicknesses, will be reflected in the relative capacitances between these elements. Because the capacitance of storage capacitor 6 is substantially larger than the capacitances of tunnel capacitors 8n, 8p (and also the parasitic gate-to-active capacitance of transistor 4), tunneling of electrons can be achieved at reasonable bias voltages to avoid damage or breakdown. This disparity in capacitive coupling is contemplated to provide excellent programming and erase performance.

Many variations in the electrical and physical construction of an analog floating-gate circuit in an integrated circuit, relative to that described above, are contemplated. From an electrical standpoint, such variations include circuits such as a reference circuit arranged as a dual floating-gate differential amplifier circuit, as known in the art. As mentioned above, examples of other analog floating-gate circuits include analog memory devices, and digital electrically programmable memory cells (including cells that may be set into one of more than two possible states, reflecting a multiple-bit data value). From a construction standpoint, such variations include other arrangements of the floating-gate device, including polysilicon-to-polysilicon floating-gate capacitors, polysilicon-to-active capacitors, and the like, and including floating-gate devices that are programmable by other mechanisms besides Fowler-Nordheim tunneling. Examples of such alternative structures are described in U.S. Patent Application Publication No. US 2013/0221418 and U.S. Pat. No. 8,779,550, both commonly assigned herewith, and in Ahuja et al., “A Very High Precision 500-nA CMOS Floating-Gate Analog Voltage Reference”, J. Solid-State Circ., Vol. 40, No. 12 (IEEE, December 2005), pp. 2364-72, all such references incorporated herein by reference. It is contemplated that those skilled in the art having reference to this specification will be readily able to realize these, and other, variations as appropriate for particular circuit applications, without undue experimentation.

As noted above, data retention has been observed to be a significant vulnerability in floating-gate devices, particularly in analog and other precision applications in which degradation of the trapped charge at the floating-gate device is reflected at the output of the circuit including that device, sometimes to such an extent that detectable loss of charge at the floating-gate device occurs over the operating life of the integrated circuit. As known in the art, the mechanism of this loss of charge is temperature accelerated, and thus can be accelerated by exposing the integrated circuit to high temperature. As such, a common accelerated life test for integrated circuits including analog floating gate devices is an unbiased bake at a temperature of at least 125 deg C. for on the order of 1000 hours.

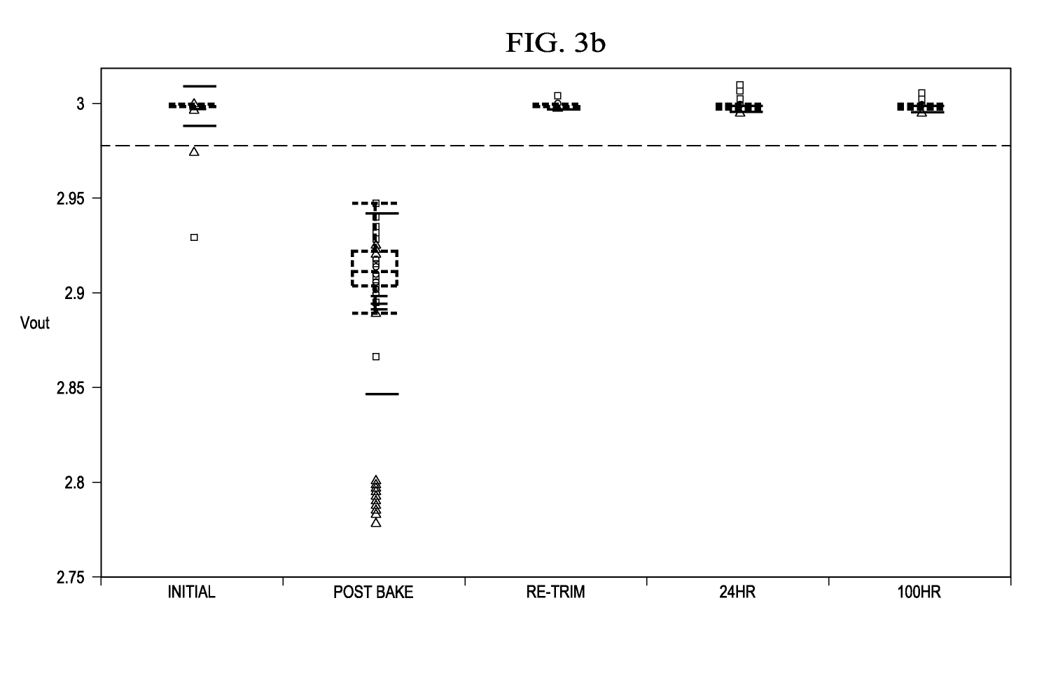

For example, FIG. 3a illustrates an example of data retention loss in a sample of analog floating-gate circuits. Specifically, the circuits in this sample are voltage reference circuits that have been trimmed to provide a desired output voltage Vout, by way of electrically programming a floating-gate capacitor. The sample analyzed in FIG. 3a includes over 150 individual circuits in wafer form, from multiple wafers over three different wafer lots. In FIG. 3a, the spread labeled “Initial” shows the output voltages of the reference circuits after initial trimming of their floating-gate devices to provide a nominal output voltage Vout of 3.00 volts; the horizontal lines indicate the standard deviation of the output voltage spreads for two of the wafer lots. After this initial trimming, the sample exhibited a mean output voltage Vout essentially at 3.00 volts, with a standard deviation of around 10 mV.

FIG. 3a also illustrates the output voltages of this same sample of integrated circuits following a 24 hour bake at 250 deg C., in its spread labeled “Post Bake”. As evident from these results, this bake caused significant and detectable retention loss, shifting the mean output voltage Vout to about 2.90 volts, with wide variation among the sample as evident by a standard deviation of about 50 mV. This experiment indicated that the charge loss varied both within wafer lots and also among wafer lots. As known in the art, the retention loss from this high temperature bake foreshadows a drift of the output voltage Vout in the overall population of these circuits over system life. This data retention loss renders analog floating-gate circuits and devices unsuitable for many precision applications.

It has been discovered, according to this invention, that the nature of the trapped charge that is lost from a floating-gate device in a data retention bake (as shown in FIG. 3a) or in system use differs from the charge that is programmed into and trapped at the floating-gate device. It has also been discovered, according to this invention, that the difference in the nature of these types of trapped charge can be used to condition the floating-gate devices, in the manufacturing process flow, so that their data retention performance over operating life is dramatically improved.

Based on experiments carried out according to this invention, it is believed that the charge lost from a programmed floating-gate device over time and temperature is the most weakly-bound charge in the device, namely that trapped charge that is at lower energy levels. These types of trapped charge in a floating-gate device are believed to include charge in dielectric material surrounding the floating-gate device due to processing (e.g., plasma charging during deposition and etch processes), and also charge trapped in the capacitor (or transistor gate) dielectric at defects caused by the electrical stress of programming and other operations that apply an electric field across the dielectric material (i.e., akin to stress-induced leakage). More specifically, the trapped charge resulting from processing amounts to charge that is already present on the device as manufactured, and does not depend on the programming operation. The electrical stress-induced trapped charge, on the other hand, largely results from the high electric fields and significant programming current involved in programming the floating-gate from its native, as-manufactured, state to the nominal trim level. In each of these cases, the trapped charge that is lost in the data retention bake is contemplated to be the same charge that would be lost from the floating-gate device over time during normal operation in its system use via Frankel-Poole conduction and other mechanisms.

In contrast, the programmed charge trapped on the floating-gate element itself (e.g., polysilicon element 16 of capacitor 6 in FIGS. 2a and 2b) is believed to be at higher energy levels than that of the processing charge and charge at stress-induced defects in the dielectric film. As known in the art, these energy levels are commonly expressed as activation energies. In this regard, it is believed that the programmed charge trapped on the floating-gate element has an activation energy of at least 1.0 eV. Conversely, it is believed that a significant amount of the bulk oxide charge (i.e., trapped charge from the manufacturing processes) and electrical stress-induced charge has an activation energy below 1.0 eV. For example, the activation energies of silicon/dielectric interface traps ranges from mid-gap (0.0 eV) to the edges of the valance and conduction bands (about 0.6 eV). To the extent that this and other unintentional (i.e., not on the floating-gate electrode) trapped charge is at an activation energy above 1.0 eV, such high energy level charge is not contemplated to affect the data retention performance of the device over normal operating lifetimes.

As mentioned above, it has been discovered, in connection with this invention, that these differences in activation energy can be used to advantage in conditioning the floating-gate devices during manufacturing test. In a general sense, embodiments of this invention carry out this conditioning by essentially removing low activation energy trapped charge, which can affect long-term data retention, and replacing that charge with high activation energy trapped charge, which is much more stable over system life. As a result, the trimmed floating-gate devices, for example in an analog circuit such as a voltage or current reference circuit, can be conditioned to ensure the long-term stability and reliability of that trim level.

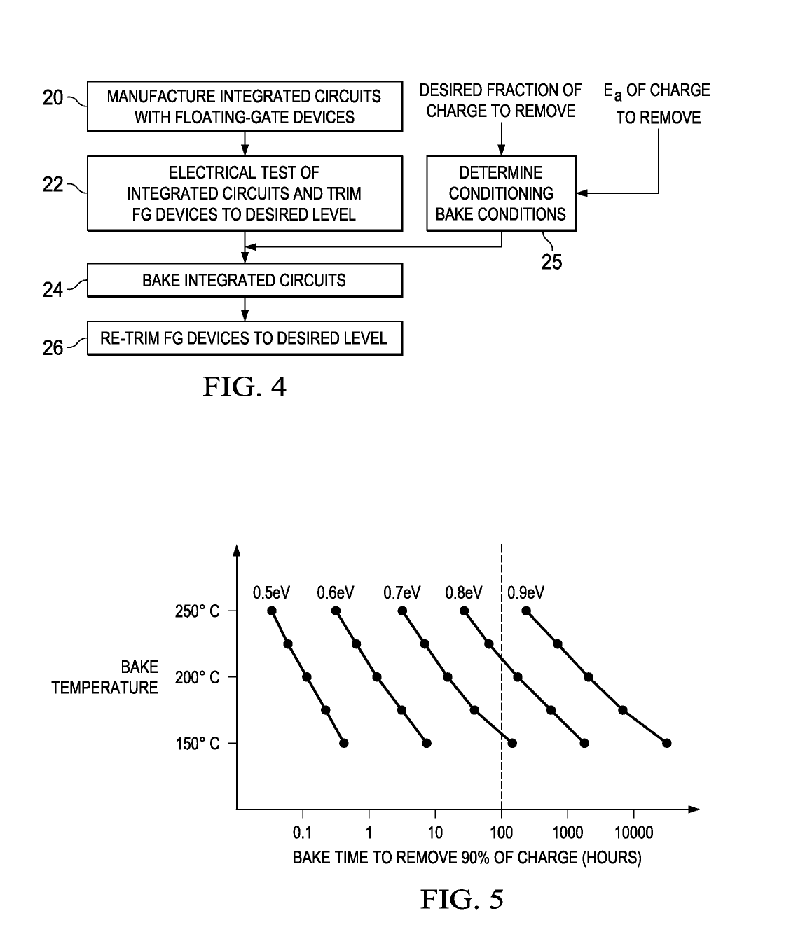

Referring now to FIG. 4, a method of manufacturing integrated circuits including analog or other circuits that include a floating-gate device to be programmed to a relatively precise trim level, according to embodiments of this invention, will now be described.

As illustrated in FIG. 4, this method begins with process 20, in which integrated circuits including programmable floating-gate devices, in particular such floating-gate devices that are to be programmed to a particular level such as used in analog and other precision circuits, are manufactured. Manufacturing process 20 may be carried out in the conventional manner for the particular technology with which the integrated circuits are to be fabricated. Examples of suitable process flows suitable for use as process 20 according to embodiments of this invention are described in the above-incorporated U.S. Patent Application Publication No. US 2013/0221418, U.S. Pat. No. 8,779,550, and the above-cited Ahuja et al. article. The programmable floating-gate devices resulting from process 20 may be in the form of capacitors such as capacitor 6 of FIGS. 2a and 2b in which one plate is electrically isolated (i.e. “floating”), or in the form of transistors in which a gate electrode is electrically isolated or floating. For the case of floating-gate capacitors, it is contemplated that various types of capacitor construction may be used, including metal-to-polysilicon capacitors such as shown in FIGS. 2a and 2b, poly-to-poly capacitors, and poly-to-active capacitors, as known in the art. Floating-gate transistors may be constructed with a single gate electrode that is electrically floating, or in transistors including multiple gate electrodes including the floating gate electrode and one or more control electrodes. In addition, as noted above, the various circuits including the floating-gate devices can vary widely, including analog or digital memory functions, voltage reference and regulator circuits such as low drop-out regulators (LDOs), to name a few. As such, it is contemplated that the types of floating-gate devices and circuits fabricated in the integrated circuits manufactured by process 20 can vary in construction.

In process 22, initial trimming of the floating-gate devices in the integrated circuits manufactured in process 20 is performed. It is contemplated that this trimming will typically be performed as part of a more extensive electrical test of the integrated circuits including the floating-gate devices, such electrical test including those functional and parametric tests suitable for the particular integrated circuits. Typically, electrical test and trim process 22 in embodiments of the invention will be performed with the manufactured integrated circuits in wafer form, for example using automated test equipment at a “multiprobe” test station as known in the art. Such testing and trimming of the integrated circuits while in wafer form can permit direct access by a probe to the programming circuitry for the floating-gate devices, or to the output of the circuit including the floating-gate device, or both. Alternatively, electrical test and trim process 22 may be performed after dicing and packaging of the integrated circuits manufactured in process 20, particularly if the circuit including the floating-gate device can be accessed directly or indirectly from an external pin.

As part of electrical test and trim process 22, the floating-gate devices that are to be conditioned according to this embodiment are programmed to a desired analog level. This programming of the floating-gate device, or “trimming” of the circuit including the device, is performed by the application of programming voltages to terminals of the floating-gate device to effect the desired charge transfer to or from the floating gate or plate element, as described above and as known in the art. This trimming may be performed by applying the programming bias as a series of pulses, with the output of the circuit sensed periodically to control the programming to stop at the desired circuit output level. Alternatively, the trimming operation may be performed in a separate electrical operation from the electrical test, with the test and trim operations performed at a different time or using different equipment from one another.

The programming involved in this trimming of the floating-gate devices in process 22 operates to develop a net charge on the floating electrode, through the operation of a mechanism such as Fowler-Nordheim tunneling. In general, the programming involves the movement of electrons through the dielectric film adjacent to the floating-gate electrode such that either electrons or holes, depending on the programming bias applied and the operative mechanism, remain trapped on the floating-gate electrode after removal of the programming bias. In the initial programming performed in electrical test and trim process 22, this trimming brings each floating-gate electrode from its native, as-manufactured, state to the desired programmed level, as reflected at the output of a circuit including the floating-gate electrode. An example of this programmed state is shown in FIG. 3a by the output voltage Vout of 3.00 volts to which the sample of devices was initially programmed (“Initial”).

According to embodiments of the invention, following electrical test and trim process 22, the trimmed integrated circuits are subjected to a conditioning bake in process 24. Conditioning bake process 24 may be performed on the integrated circuits in the same form as in electrical test and trim process 22, such as in wafer form, or alternatively may be performed following other processing including packaging and the like. As will be described in further detail below, conditioning bake process 24 is intended to cause the loss of some charge from the floating-gate devices programmed in process 22, specifically that charge that is relatively weakly held in the device and that would be vulnerable to loss during the system life of the integrated circuit.

In this regard, according to the embodiment shown in FIG. 4, the particular conditions of conditioning bake process 24 are determined in process 25. As noted above, it has been discovered, according to this invention, that the types of charge that is most vulnerable to loss over the operating life of the floating-gate device are those that are held by a temperature-activated mechanism, and that have relatively low activation energies, as noted above. According to some embodiments of the invention, the conditions of conditioning bake process 24 are selected, in process 25, so as to remove a desired fraction of charge that is at a particular activation energy and lower. Accordingly, inputs into determining process 25 include an estimate of an activation energy Eₐ of the charge to be removed, and the desired fraction of that charge to be removed from the floating-gate devices.

According to one approach, process 25 is performed based on knowledge of the temperature acceleration of charge loss. FIG. 5 illustrates time vs. temperature plots corresponding to the removal of at least 90% of charge from a floating-gate device, for charge types of various activation energies ranging from 0.5 eV to 0.9 eV. It is believed, in connection with this embodiment, that trapped charge having an activation energy greater than 1.0 eV is at a sufficiently high energy level as to be unlikely to be lost over the operating life of the integrated circuit at expected temperature and operating conditions. Accordingly, conditioning bake process 24 in this embodiment is directed to that charge at activation energies below 1.0 eV, as shown in FIG. 5.

The plots of FIG. 5 are based on the well-known Arrhenius equation:

$$n ( t ) = n ( 0 ) exp [ vt \cdot exp ( - \frac{{E}_{a}}{kT} ) ]$$

where n(t) is the number of charges (electron charge) at time t, Eₐ is the activation energy (eV), v is the collision frequency (sec⁻¹), T is the temperature (deg K), and k is Boltzmann's constant. For the plots of FIG. 5, collision frequency v is estimated at 1.2E+03 sec⁻¹ from data corresponding to an activation energy Eₐ of 1.0 eV at 150 deg C. The plots of FIG. 5 are thus calculated by solving the Arrhenius equation for the value of time t at which n(t)=0.90n(0), at bake temperatures ranging from 150 deg C. to 250 deg C. in 25 degree steps, and for each of the activation energies Eₐ=[0.5 eV, 0.6 eV, 0.7 eV, 0.8 eV, 0.9 eV].

According to this embodiment, process 25 is determined by selecting a combination of bake time and bake temperature that is predicted by the Arrhenius equation, or by another approach, to remove a selected fraction of trapped charge, at a selected activation energy or lower, from a floating-gate device such as that in the integrated circuits manufactured in process 20. The selected activation energy of the charge to be removed may be estimated by way of experiment, or may be based on prior analyses. Referring to FIG. 5, a bake of about 100 hours at about 175 deg C. would be predicted to remove at least about 90% of trapped charge at activation energies Eₐ of 0.7 eV and lower. Similarly, a bake of about 24 hours at a temperature of about 250 deg C. would be predicted to remove at least about 90% of trapped charge at activation energies Eₐ of 0.8 eV and lower. In any case, it is contemplated that conditioning bake process 24 will typically have a duration of at least about four hours, and will typically be at a temperature of at least 125 deg C.

Of course, other approaches for determining the conditions of conditioning bake process 24 may alternatively be used. It is contemplated, however, that such other approaches will consider the nature of the trapped charges, the amount of charge to be removed, and the like. In addition, whether the Arrhenius equation or other approaches are followed, other factors may also enter into the determination of process 25 in selecting the particular conditions of conditioning bake process 24. For example, the bake may need to be performed at or below a maximum temperature of the bake equipment or a maximum temperature that may be tolerated by the integrated circuits. In addition, the time involved for the conditioning bake is necessarily limited by the desired manufacturing cycle time; for example, a bake of more than 24 hours would commonly be undesirable.

Following conditioning bake process 24 at the conditions determined in process 25, re-trim process 26 is then performed on the conditioned integrated circuits as shown in FIG. 5. According to embodiments of the invention, re-trim process 26 again trims the floating-gate devices to replace charge that was lost in conditioning bake 24. As in process 22, it is contemplated that the re-trim of process 26 will be performed by programming while monitoring an output voltage from the circuit including the floating-gate devices being programmed, to ensure that the re-trim reaches but does not significantly exceed the desired level. It is contemplated that the amount of charge programmed (i.e., crossing the dielectric film to be trapped at the floating-gate electrode) in re-trim process 26 will typically be much less than the amount of charge programmed in the initial trimming of process 22. This can be seen, by analogy, from FIG. 3a in which the loss of charge shown in the “Post Bake” column, following a 24 hour bake at 250 deg C., amounts to a shift of output voltage Vout by an average of 100 mV, at a standard deviation of about 50 mV. The change in output voltage effected by the original trimming of process 22 is typically much larger, on the order of volts for the example of FIG. 3a.

The level to which re-trim process 26 programs the floating-gate devices need not necessarily match the level initially programmed in process 22. It is contemplated, however, that the re-trim level should be at least as heavily programmed as in initial programming process 22 (i.e., the magnitude of charge at the floating-gate electrode after re-trim is equal to or greater than that after the initial programming, whether referring to trapped electrons or holes), given the variability of charge loss among a population of devices caused by conditioning bake process 24. If the desired re-trim level is less than that of the originally-programmed level, some devices that exhibit little or no data retention loss may have a programmed level following conditioning bake 24 greater than the ultimate desired level of re-trim process 26.

Furthermore, according to some embodiments, it is desirable that the level to which re-trim process 26 programs the floating-gate devices is the same to which the initial programming of process 22 trimmed those devices. As noted above, it is believed that one of the types of charge vulnerable to data retention loss is that charge which is trapped in electrical stress-induced sites in the dielectric of the floating-gate device. It is further believed that the charge that becomes trapped in those electrical stress-induced sites correlates with the amount of programming charge passing through the dielectric in the trimming operation, i.e. increases with the magnitude of the programming charge. Assuming that stress-induced trapped charge is essentially removed by conditioning bake 24 (i.e., that charge type having relatively low activation energy), minimizing the extent of the programming in re-trim step 26 would result in less trapped charge at these stress-induced trap sites. This minimization would be accomplished by re-trim process 26 programming the floating-gate devices to no more than about the same level than that originally programmed in the trimming of process 22.

Similarly as for processes 22, 24, re-trim process 26 may be performed with the integrated circuits still in wafer form (for those implementations in which processes 22, 24 are performed at the wafer level, of course), or alternatively after the packaging or other processing of those integrated circuits. If re-trim process 26 is performed after packaging, however, some provision for direct or indirect access to the circuit including the floating-gate devices must be provided, in order to ensure that the re-trim of those devices is performed to the desired programming level.

It has been observed from experiment, in connection with this invention, that the process described above according to those embodiments significantly improves the data retention performance of floating-gate devices. FIG. 3b illustrates the post re-trim performance of the same sample as shown in FIG. 3a, for which the output voltage Vout degraded by about 100 mV on average, from a 24 hour bake at 250 deg C. As shown in FIG. 3b by the column indicated “Re-Trim”, re-trim process 26 restored the nominal output voltage Vout to 3.00 volts to the sample. But following this re-trim, the data retention performance of this sample improved significantly from that following the initial programming, with output voltage Vout remaining essentially flat after a 24 hour bake at 125 deg C., and then again after 100 hours of the bake at 125 deg C. Subsequent data has indicated that this excellent data retention continued for this sample out to 800 hours of the 125 deg C. bake, with less than 0.5% loss exhibited after that extended bake. In addition, this minimal data retention loss over that extended bake also exhibited little variation among the sample, both from wafer-to-wafer within the same lot and among wafer lots. It is therefore contemplated that the excellent data retention of floating-gate devices conditioned by embodiments of this invention will be exhibited over the expected life of the integrated circuits including these devices in system use.

As such, it is believed, according to this invention, and has been borne out by experiment, that the charge lost from the floating-gate devices by way of conditioning bake process 24 is that of relatively low activation energies, and thus the easiest charge to remove by temperature activation, while the charge re-programmed in re-trim process 26 is that of relatively high activation energy (e.g., charge trapped on the floating-gate electrode), and thus much more difficult to remove by temperature activation. Because temperature-activated mechanisms tend to dominate data retention loss in floating-gate devices, embodiments of this invention can provide significant improvement in the data retention performance of integrated circuits.

In addition, embodiments of this invention can be efficiently implemented into the overall manufacturing and test flow without undue cost or complexity. Equipment costs are minimized, in that only ovens for the conditioning bake and an additional electrical test operation for the re-trim are added to the process flow. Complex and costly additions to the fabrication test flow, such as are involved in the deposition and removal of dielectric films specific to the floating-gate devices, are avoided.

While one or more embodiments have been described in this specification, it is of course contemplated that modifications of, and alternatives to, these embodiments, such modifications and alternatives capable of obtaining one or more the advantages and benefits of this invention, will be apparent to those of ordinary skill in the art having reference to this specification and its drawings. It is contemplated that such modifications and alternatives are within the scope of this invention as subsequently claimed herein.

What is claimed is:

1. A method of setting a trim level of an analog circuit in a semiconductor integrated circuit, the analog circuit including a floating-gate device, the method comprising the steps of:
electrically programming the floating-gate device to a first trim level;
then baking the integrated circuit at an elevated temperature for a selected duration;
then again electrically programming the floating-gate device to a second trim level equal to or greater than about the first trim level.

2. The method of claim 1, wherein the second trim level is equal to about the first trim level.

3. The method of claim 1, wherein the step of electrically programming the floating-gate device to a first trim level is performed with the integrated circuit in wafer form;
and wherein the baking step comprises baking the wafer including the integrated circuit.

4. The method of claim 1, wherein the baking step operates to remove charge from the programmed floating-gate device;
and further comprising:
estimating an activation energy of a type of charge removed by the baking step; and
based on the activation energy, selecting the elevated temperature and duration of the baking step to remove a selected amount of the type of charge.

5. The method of claim 1, wherein the selected duration of the baking step is at least about four hours.

6. The method of claim 5, wherein the elevated temperature is at least about 125 deg C.

7. The method of claim 1, wherein the elevated temperature is at least about 150 deg C.;
and wherein the selected duration is at least about 24 hours.

8. The method of claim 1, wherein the elevated temperature is at least about 200 deg C.;
and wherein the selected duration is at least about 10 hours.

9. The method of claim 1, wherein the elevated temperature is about 250 deg C.;
and wherein the selected duration is at least about 4 hours.

10. A method of manufacturing a semiconductor integrated circuit, the integrated circuit including a floating-gate device, the method comprising the steps of:
fabricating a floating-gate device at a semiconductor surface of a body;
applying programming voltages to the floating-gate device to store charge at the device corresponding to a first trim level;
then baking the integrated circuit at an elevated temperature for a selected duration;
then applying programming voltages to the floating-gate device to store charge at the device corresponding to a second trim level equal to or greater than about the first trim level.

11. The method of claim 10, wherein the baking step operates to remove stored charge from the floating-gate device;
and further comprising:
estimating an activation energy of a type of charge removed by the baking step; and
based on the activation energy, selecting the elevated temperature and duration of the baking step to remove a selected amount of the type of charge.

12. The method of claim 10, wherein the second trim level is equal to about the first trim level.

13. The method of claim 10, wherein the fabricating step fabricates a plurality of integrated circuits at the semiconductor surface of a wafer, each of the plurality of integrated circuits including a floating-gate device;
wherein the step of applying programming voltages to store charge corresponding to a first trim level is performed for each of the integrated circuits on the wafer;
and wherein the baking step comprises baking the wafer at the elevated temperature for the selected duration.

14. The method of claim 10, wherein the selected duration of the baking step is at least about four hours.

15. The method of claim 14, wherein the elevated temperature is at least about 125 deg C.

16. The method of claim 10, wherein the elevated temperature is at least about 150 deg C.;
and wherein the selected duration is at least about 24 hours.

17. The method of claim 10, wherein the elevated temperature is at least about 200 deg C.;
and wherein the selected duration is at least about 10 hours.

18. The method of claim 10, wherein the elevated temperature is about 250 deg C.;
and wherein the selected duration is at least about 4 hours.
